(19) United States
(12) Patent Application Publication
(10) Pub. No.: US 2025/0036127 A1
(43) Pub. Date: Jan. 30, 2025

(54) DATA-ANALYSIS-BASED CONTROL OPTIMIZATION FOR HOT-AIR BALLOON FLIGHT

(71) Applicant: INTERNATIONAL BUSINESS MACHINES CORPORATION, Armonk, NY (US)

(72) Inventors: Sarbajit K. RAKSHIT, Kolkata (IN); Siddique M. ADONI, Bangalore (IN); Partho GHOSH, Kolkata (IN); Lakshmi Soumya SUGGALA, Visakhapatnam (IN)

(21) Appl. No.: 18/357,250

(22) Filed: Jul. 24, 2023

(51) Int. Cl. G05D 1/10; G06F 30/15

(52) U.S. Cl. CPC G05D 1/106; G06F 30/15; B64B 1/40

(57) ABSTRACT

Hot-air balloon flight is facilitated by obtaining a data-analysis-based control to selectively redirect the flight path of the hot-air balloon, where the hot-air balloon includes a positioning system to facilitate repositioning the hot-air balloon. The data-analysis-based control includes simulating a digital twin model of the hot-air balloon and one or more environmental conditions to potentially effect the hot-air balloon on a projected flight path, and based on the simulated digital twin model, forecasting presence of an adverse environmental condition to effect the hot-air balloon on the projected flight path. Further, the data-analysis-based control includes controlling the positioning system of the hot-air balloon to reposition the hot-air balloon onto a different flight path than the projected flight path to mitigate impact of the adverse environmental condition on the hot-air balloon.

### BACKGROUND

This disclosure relates generally to data analysis, and in particular, to a data-analysis-based control for an object.

There are a variety of types of hot-air balloon configurations in use. In general, a hot-air balloon floats due to the buoyant force exerted on it by increasing air temperature inside the envelope, making the inside air less dense than surrounding ambient air. The amount of lift provided by a hot-air balloon depends primarily on the temperature difference between the inside air of the envelope and the ambient air around the envelope.

### SUMMARY

Certain shortcomings of the prior art are overcome, and additional advantages are provided herein through the provision of a computer-implemented method which includes obtaining a data-analysis-based control to control a flight path of a hot-air balloon, where the hot-air balloon includes a positioning system to facilitate repositioning the hot-air balloon. The data-analysis-based control includes simulating a digital twin model of the hot-air balloon and one or more environmental conditions to potentially effect the hot-air balloon on a projected flight path, and forecasting, based on the simulated digital twin model of the hot-air balloon and the one or more environmental conditions, presence of an adverse environmental condition to effect the hot-air balloon on the projected flight path. In addition, the data-analysis-based control includes controlling, based on the forecasted adverse environmental condition on the projected flight path, the positioning system of the hot-air balloon to reposition the hot-air balloon onto a different flight path than the projected flight path to mitigate impact of the adverse environmental condition on the hot-air balloon.

Computer systems and computer program products relating to one or more aspects are also described and claimed herein. Further, services relating to one or more aspects are also described and may be claimed herein.

Additional features and advantages are realized through the techniques described herein. Other embodiments and aspects are described in detail herein and are considered a part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1 depicts one example of a computing environment to include and/or use one or more aspects of the present disclosure;

FIG. 2 depicts one embodiment of a computer program product with a context-aware balloon flight control module, in accordance with one or more aspects of the present disclosure;

FIG. 3 depicts one embodiment of context-aware balloon flight control processing, in accordance with one or more aspects of the present disclosure;

FIG. 4A depicts one embodiment of a high altitude hot-air balloon to include and/or use context-aware balloon flight control, in accordance with one or more aspects of the present disclosure;

FIG. 4B depicts another embodiment of a hot-air balloon to include and/or use context-aware balloon flight control, in accordance with one or more aspects of the present disclosure;

FIG. 5A is a further example of a computing environment to include and/or use one or more aspects of the present disclosure;

FIG. 5B depicts one example of a simulated digital twin model of a hot-air balloon for a context-aware balloon flight control, in accordance with one or more aspects of the present disclosure;

FIG. 6 depicts a further example of a computing environment to include and/or use one or more aspects of the present disclosure;

FIG. 7A depicts one example of a context-aware balloon flight control workflow, in accordance with one or more aspects of the present disclosure;

FIG. 7B depicts another example of a context-aware balloon flight control workflow, in accordance with one or more aspects of the present disclosure; and

FIGS. 8A & 8B depict data-analysis-based control of a hot-air balloon to reposition the hot-air balloon to a flight path which mitigates potential impact of an adverse environmental condition on the hot-air balloon, in accordance with one or more aspects of the present disclosure.

### DETAILED DESCRIPTION

The accompanying figures, which are incorporated in and form a part of this specification, further illustrate the present disclosure and, together with this detailed description of the disclosure, serve to explain aspects of the present disclosure. Note in this regard that descriptions of well-known systems, devices, processing techniques, etc., are omitted so as to not unnecessarily obscure the disclosure in detail. It should be understood, however, that the detailed description and this specific example(s), while indicating aspects of the disclosure, are given by way of illustration only, and not limitation. Various substitutions, modifications, additions, and/or other arrangements, within the spirit or scope of the underlying inventive concepts will be apparent to those skilled in the art from this disclosure. Note further that numerous inventive aspects or features are disclosed herein, and unless inconsistent, each disclosed aspect or feature is combinable with any other disclosed aspect or feature as desired for a particular application of the concepts disclosed.

Note also that illustrative embodiments are described below using specific code, designs, architectures, protocols, layouts, schematics, systems, or tools only as examples, and not by way of limitation. Furthermore, the illustrative embodiments are described in certain instances using particular software, hardware, tools, and/or data processing environments only as example for clarity of description. The illustrative embodiments can be used in conjunction with other comparable or similarly purposed structures, systems, applications, architectures, etc. One or more aspects of an illustrative control embodiment can be implemented in software, hardware, or a combination thereof.

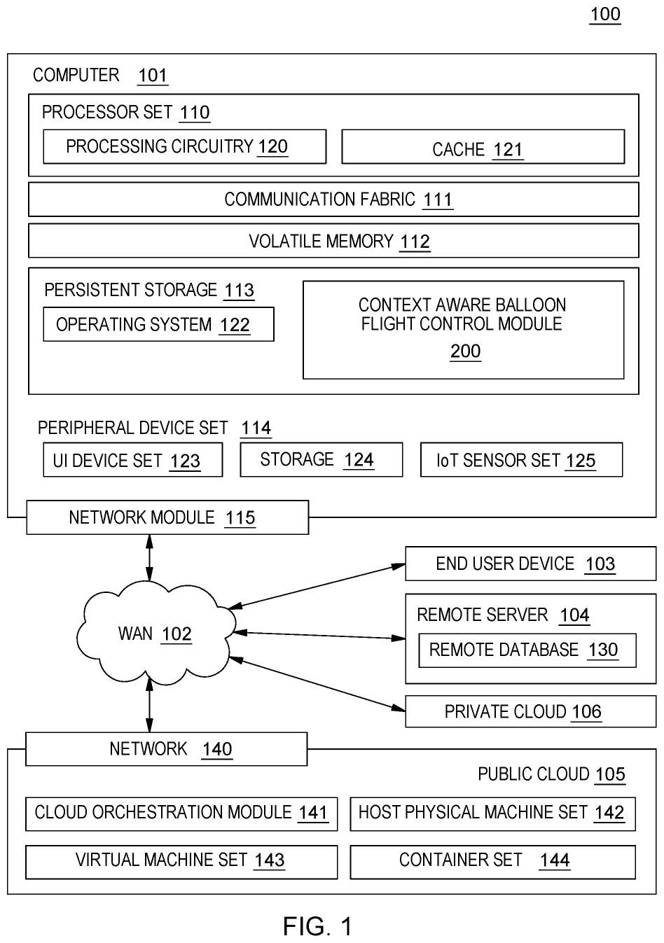

As understood by one skilled in the art, program code, as referred to in this application, can include software and/or hardware. For example, program code in certain embodiments of the present disclosure can utilize a software-based implementation of the functions described, while other embodiments can include fixed function hardware. Certain embodiments combine both types of program code. Examples of program code, also referred to as one or more programs, are depicted in FIG. 1, including operating system 122 and context-aware balloon flight control module 200, which are stored in persistent storage 113.

One or more aspects of the present disclosure are incorporated in, performed and/or used by a computing environment. As examples, the computing environment can be of various architectures and of various types, including, but not limited to: personal computing, client-server, distributed, virtual, emulated, partitioned, non-partitioned, cloud-based, quantum, grid, time-sharing, clustered, peer-to-peer, mobile, having one node or multiple nodes, having one processor or multiple processors, and/or any other type of environment and/or configuration, etc., that is capable of executing a process (or multiple processes) that, e.g., perform context-aware balloon flight control processing, such as disclosed herein. Aspects of the present disclosure are not limited to a particular architecture or environment.

Prior to further describing detailed embodiments of the present disclosure, an example of a computing environment to include and/or use one or more aspects of the present disclosure is discussed below with reference to FIG. 1.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as context-aware balloon flight control module block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

The computing environment described above is only one example of a computing environment to incorporate, perform and/or use one or more aspects of the present disclosure. Other examples are possible. Further, in one or more embodiments, one or more of the components/modules of FIG. 1 need not be included in the computing environment and/or are not used for one or more aspects of the present disclosure. Further, in one or more embodiments, additional and/or other components/modules can be used. Other variations are possible.

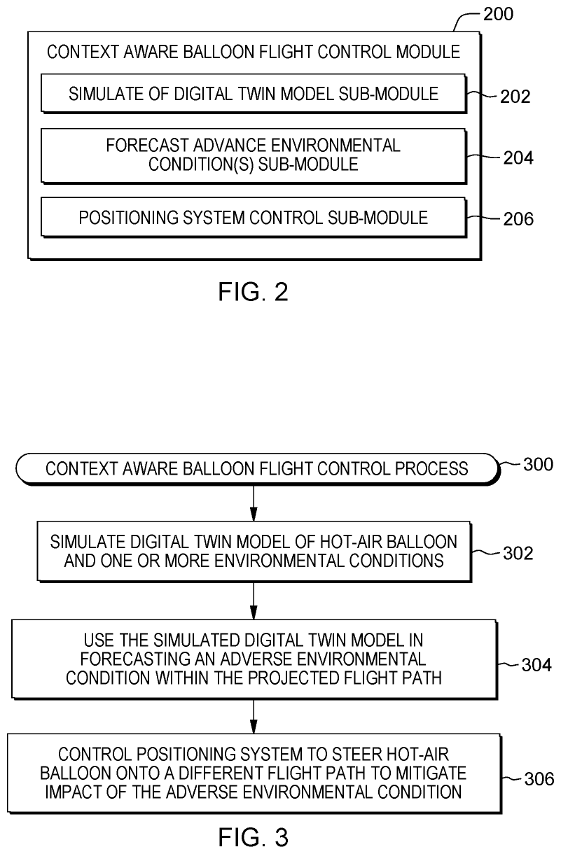

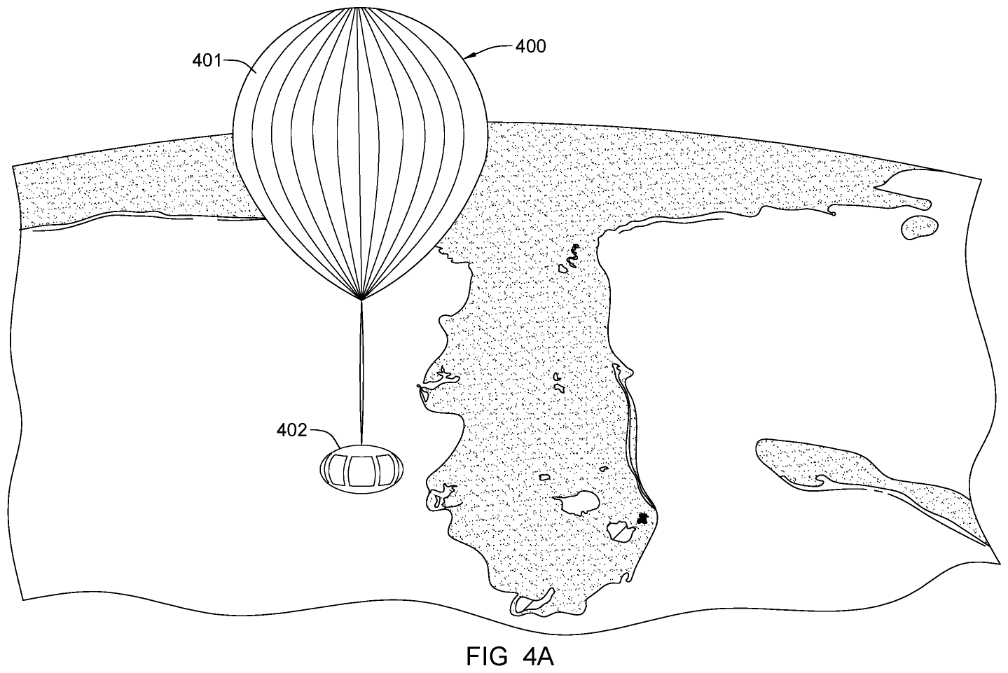

By way of example, one or more embodiments of a context-aware balloon flight control module and process are described initially with reference to FIGS. 2-3. FIG. 2 depicts one embodiment of context-aware balloon flight control module 200 that includes code or instructions to perform context-aware balloon flight control processing, in accordance with one or more aspects of the present disclosure, and FIG. 3 depicts one embodiment of a context-aware balloon flight control process, in accordance with one or more aspects of the present disclosure.

Referring to FIGS. 1-2, context-aware balloon flight control module 200 includes, in one example, various sub-modules used to perform processing, in accordance with one or more aspects of the present disclosure. The sub-modules are, e.g., computer-readable program code (e.g., instructions) and computer-readable media (e.g., persistent storage (e.g., persistent storage 113, such as a disk) and/or a cache (e.g., cache 121), as examples). The computer-readable media can be part of a computer program product and can be executed by and/or using one or more computers, such as computer(s) 101; processors, such as a processor of processor set 110; and/or processing circuitry, such as processing circuitry of processor set 110, etc.

As noted, FIG. 2 depicts one embodiment of a context-aware balloon flight control module 200 which, in one or more embodiments, includes, or provides, a control, or data-analysis-based control, to control a flight path of a hot-air balloon, where the hot-air balloon includes a positioning system to facilitate repositioning the hot-air balloon. In the embodiment of FIG. 2, example sub-modules of context-aware balloon flight control module 200 include a simulate digital twin model sub-module 202 to simulate a digital twin model of the hot-air balloon and one or more environmental conditions to potentially effect the hot-air balloon on a projected flight path, and a forecast adverse environmental condition(s) sub-module 204 to forecast presence of one or more adverse environmental conditions to potentially effect the hot-air balloon on the projected flight path, where the forecasting is based on the simulated digital twin model of the hot-air balloon and the one or more environmental conditions. In addition, context-aware balloon flight control module 200 includes, in one embodiment, a positioning system control sub-module 206 to control the positioning system, based on the forecasted adverse environmental condition on the projected flight path, to reposition the hot-air balloon to a different flight path than the projected flight path to mitigate impact of the adverse environmental condition(s) on the hot-air balloon. Advantageously, intelligent, data-analysis-based control of a flight path of a hot-air balloon is provided to mitigate certain disadvantages of hot-air balloon flight. The data-analysis-based control, in one embodiment, dynamically controls a positioning system of the hot-air balloon (e.g., via one or more control signals, such as one or more activation signals) to reposition the hot-air balloon to a different flight path than a projected flight path with a forecasted adverse environmental condition(s). Note that although various sub-modules are described, context-aware balloon flight control module processing such as disclosed herein can use, or include, additional, fewer, and/or different sub-modules. A particular sub-module can include additional code, including code of other sub-modules, or less code. Further, additional and/or other modules can be used. Many variations are possible.

In one or more embodiments, the sub-modules are used, in accordance with one or more aspects of the present disclosure, to perform context-aware balloon flight control processing. FIG. 3 depicts one example of a context-aware balloon flight control process, such as disclosed herein. The process is executed, in one or more examples, by a computer (e.g., computer 101 (FIG. 1)), and/or a processor or processing circuitry (e.g., of processor set 110 of FIG. 1). In one example, code or instructions implementing the process, are part of a module, such as context-aware balloon flight control module 200. In other examples, the code can be included in one or more other modules and/or in one or more sub-modules of the one or more other modules. Various options are available.

As one example, context-aware balloon flight control process 300 executing on a computer (e.g., computer 101 of FIG. 1), a processor (e.g., a processor of processor set 110 of FIG. 1), and/or processing circuitry (e.g., processing circuitry of processor set 110), simulates a digital twin model of the hot-air balloon and one or more environmental conditions to potentially effect the hot-air balloon on a projected flight path 302. In one embodiment, simulating the digital twin model and the one or more environmental conditions occurs in real time and can occur concurrent with flight of the hot-air balloon being simulated. Note that a digital twin model, or a digital twin, is a virtual model designed to accurately reflect a physical object, such as a hot-air balloon. In one embodiment, the hot-air balloon is provided with sensors, such as Internet of Thing (IoT) sensors to produce data on different aspects of the hot-air balloon and the balloon's performance, with the data and the virtual model being used to run simulations, such as simulations with one or more environmental conditions that may potentially affect the hot-air balloon on a projected flight path. In one or more embodiments, the digital twin model is a virtual environment which can be used to run a number of simulations to study multiple processes involving the hot-air balloon.

In one or more embodiments, context-aware balloon flight control processing 300 further includes using the simulated digital twin model in forecasting presence of one or more adverse environmental conditions to potentially effect the hot-air balloon on the projected flight path 304. The adverse environmental condition(s) can be any of a variety of potential adverse environmental conditions, including, for instance, a physical obstruction, another hot-air balloon, an adverse air quality issue, a weather issue, etc. Further, context-aware balloon flight control processing 300 includes, in one embodiment, controlling a positioning system of the hot-air balloon to reposition the hot-air balloon to a different flight path than the projected flight path to mitigate impact of the adverse environmental condition(s) of the hot-air balloon 306. The positioning system can be any of a variety of positioning systems forming a part of, or connected to, the hot-air balloon. For instance, precision thrusters and/or one or more rotatable air-moving devices can be coupled to the hot-air balloon, such as to a basket or gondola of the hot-air balloon, to facilitate moving or repositioning the hot-air balloon from a projected flight path to a different flight path. In one embodiment, the precision thrusters can be one or more propane-powered thrusts and the one or more rotatable air-moving devices can be one or more electric-powered rotatable air-moving devices, with one or more appropriate energy sources for the positioning system being incorporated into the hot-air balloon.

Generally stated, disclosed herein are computer-implemented methods, computer systems, and computer program products for facilitating data-analysis-based control of a flight path of a hot-air balloon, where the hot-air balloon includes a positioning system to facilitate repositioning of the hot-air balloon. The control is a data-analysis-based control configured to simulate a digital twin model of the hot-air balloon and one or more environmental conditions to potentially effect the hot-air balloon on a projected flight path. In one embodiment, the simulation can be in real time, and concurrent with the hot-air balloon flight. Based on the simulated digital twin model of the hot-air balloon and the one or more environmental conditions, the data-analysis-based control can forecast presence of an adverse environmental condition to effect the hot-air balloon on the projected flight path, and based on the forecasted adverse environmental condition(s) on the projected flight path, controls the positioning system of the hot-air balloon to reposition the hot-air balloon onto a different flight path than the projected flight path to mitigate impact of the adverse environmental condition(s) on the hot-air balloon.

In one or more embodiments, simulating the digital twin model with the one or more environmental conditions includes using, by the data-analysis-based control, satellite image data analysis to predict air quality at different altitudes of the projected flight path, where the one or more environmental conditions to potentially effect the hot-air balloon include the predicted air quality at the different altitudes of the projected flight path.

In one embodiment, predicting the air quality at different altitudes of the projected flight path includes using, by the data-analysis-based control, refraction of light data analysis to determine from the satellite image data presence of one or more adverse air qualities within the projected flight path of the hot-air balloon.

In one or more implementations, the data-analysis-based control further includes modeling in 3-D space, along with the digital twin model, an environmental condition of the one or more environmental conditions, and wherein the data-analysis-based control controls the positioning system of the hot-air balloon to reposition the hot-air balloon onto a different flight path to avoid the adverse environmental condition using, at least in part, the modeling in 3-D space of the environmental condition. In one embodiment, the environmental condition includes a presence of aerosols at one or more different altitudes, and the modeling includes modeling of concentration of different particles at one or more different altitudes, and spread of the one or more different particles in 3-D space to facilitate identifying the different flight path for the hot-air balloon, there the different flight path has a lower concentration of the one or more different particles than the projected flight path.

In one or more embodiments, the data-analysis-based control further includes generating, at least in part, the simulated digital twin model, a lift characterization of the hot-air balloon, and one or more corresponding air parameters. In addition, the control includes using, at least in part, the lift characterization of the hot-air balloon and the one or more corresponding air parameters in controlling the positioning system to reposition the hot-air balloon to the different flight path to mitigate impact of the adverse condition on the hot-air balloon.

In one or more embodiments, the data-analysis-based control further includes obtaining multifarious data for the hot-air balloon and the one or more environmental conditions, and using the multifarious data in simulating the digital twin model and the one or more environmental conditions in real time to simulate conditions of flight dynamics of the hot-air balloon with context awareness. In one embodiment, the multifarious data includes data selected from the group consisting of: data properties of the hot-air balloon, data properties of flight of the hot-air balloon, weather data related to flight of the hot-air balloon, and particle concentration at different altitudes of the projected flight path.

In one or more embodiments, the data-analysis-based control further includes generating a dynamic geofence around the hot-air balloon based on flight direction and speed, and using the dynamic geofence around the hot-air balloon to identify a potential air-gap conflict between the hot-air balloon and another structure, where the adverse environmental condition includes the potential air-gap conflict. The controlling of the positioning system includes taking corrective action to avoid the potential air-gap conflict between the hot-air balloon and the other structure.

In one or more embodiments, the simulating further includes simulating a landing site for the hot-air balloon, and the data-analysis-based control further includes auto-adjusting a landing flight path of the hot-air balloon using the positioning system during descent of the hot-air balloon based on simulating the landing site.

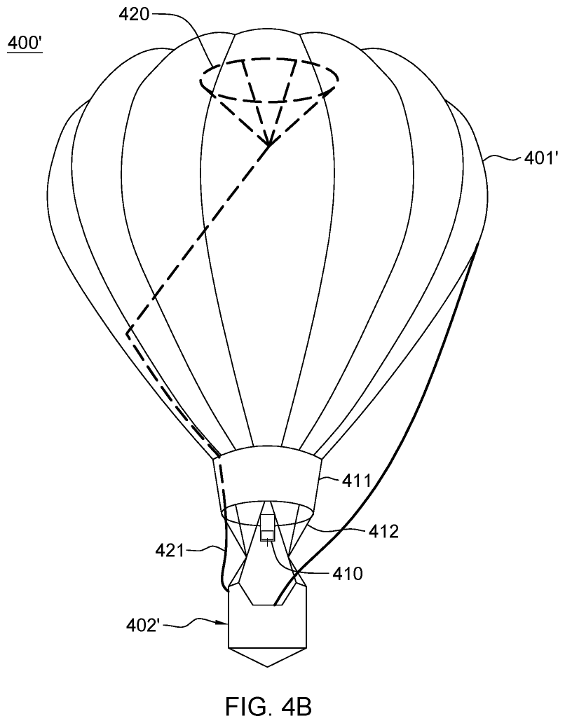

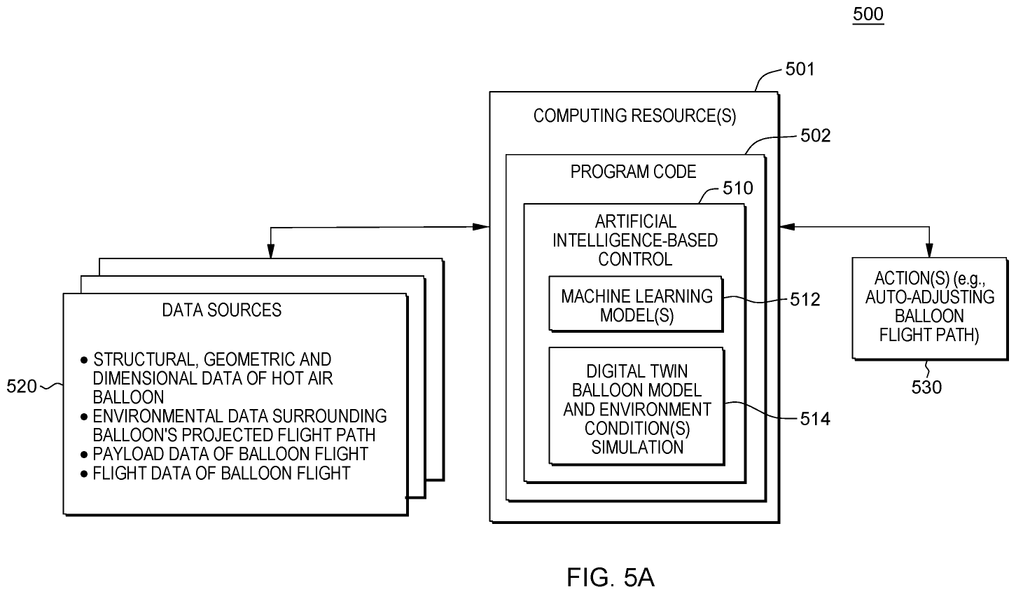

By way of example, FIG. 4A depicts one embodiment of a high-altitude hot-air balloon 400 which includes an envelope 401, and a gondola 402. As illustrated, hot-air balloon 400 is shown at a high altitude, such as two or three times higher than commercial flight travel, so that the balloon is high enough to see the Earth's curvature. High-altitude hot-air balloon 400 is one example of a balloon which can include and/or use context-aware balloon flight control, in accordance with one or more aspects of the present disclosure.

FIG. 4B depicts a more conventional hot-air balloon embodiment, which can include and/or use context-aware balloon flight control, in accordance with one or more aspects of the present disclosure. As illustrated in FIG. 4B, hot-air balloon 400′ includes an envelope 401′ and a gondola (or basket) 402′. In the embodiment of FIG. 4B, gondola 402′ is configured as an open-air basket where passengers and a pilot stand.

Hot-air balloon 400′ further includes a burner 410 which propels heat up inside of envelope 401′, which is the balloon fabric that holds the air. The utilization of hot air to create buoyancy, which generates lift, is the underlying concept underpinning hot-air balloon physics. A hot-air balloon is made up of a huge bag called an envelope that is suspended underneath a gondola or basket. A burner, such as burner 410 (typically with several megawatts of power), heats air inside the envelope through an aperture formed by a skirt 411, with suspension cables 412 coupling the gondola or basket to the envelope 401′. The hot air inside the envelope has a lower density than the cooler air outside, and due to the buoyant force caused by the surrounding air, the hot-air balloon is lifted off the ground due to the density differential. The principle behind this lift is called Archimedes principle, which states that any object (regardless of its shape) that is suspended in a fluid is acted upon by an upward, buoyant force equal to the weight of the fluid displaced by the object.

If the balloon operator wants to bring the hot-air balloon down, the operator either turns OFF the burner, which cools the hot air in the envelope and reduces the buoyant force, or the operator can open a small vent (or deflation port) 420 at the top of envelope 401′, via a control line (or valve line) 421. This allows some of the hot air to escape, lowering the buoyancy and leading the balloon to descend in a controlled manner.

In flight, the balloon operator ignites the burner intermittently to maintain a constant height, then turns it OFF after the desired altitude is reached. As a result, the hot-air balloon rises and falls. Because maintaining a strictly constant height by maintaining a net-zero buoyant force on the hot-air balloon is difficult, this is the traditional approach to maintaining an approximately constant altitude.

There can be a variety of issues with hot-air balloon flight including, for instance, undesirable landing sites, abrupt and sudden significant weather risks to ballooning (e.g., a high-wind landing can pose a danger of injury), fog or precipitation (which can cause sudden loss of visibility), unseen impedances (such as electrical wires or antennae, which are examples of non-weather related adverse environmental conditions), landing with a hard landing, crashing into another balloon above or nearby, experiencing a shortage of burning fuel, and during a landing sequence, gondola dragging, tipping, and/or bouncing, can cause occupant injury.

In addition, high-altitude “space” travel with hot-air balloons is currently of interested in the industry. With high-altitude hot-air balloon travel, further adverse environmental conditions can be experienced including, for instance, the presence of aerosols at different altitudes, including different concentrations of different particles at different altitudes. Depending on the particles and the concentrations, the aerosols can represent an adverse environmental condition to the hot-air balloon flight. Note in this regard that aerosols is used in the general sense as including, for instance, presence of CO₂, smog with different chemical particles, dust particles, etc., including, for instance sulfur dioxide, one or more of which could cause an adverse reaction with the hot-air balloon, such as the envelope material of the hot-air balloon, potentially effecting the lifetime of the balloon, or otherwise negatively impacting the hot-air balloon flight.

Advantageously, in on aspect, intelligent, data-analysis-based control of a flight path of a hot-air balloon is provided herein to mitigate certain disadvantages of hot-air balloon flight. The data-analysis-based control, in one or more embodiments, dynamically controls a positioning system of the hot-air balloon (e.g., via one or more control signals) to reposition the hot-air balloon to a different flight path than a projected flight path with a determined adverse environmental condition(s).

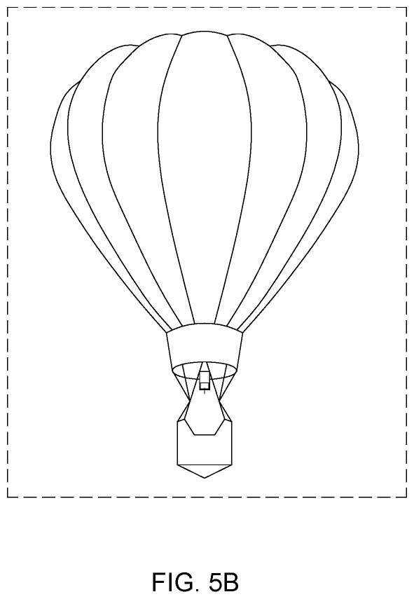

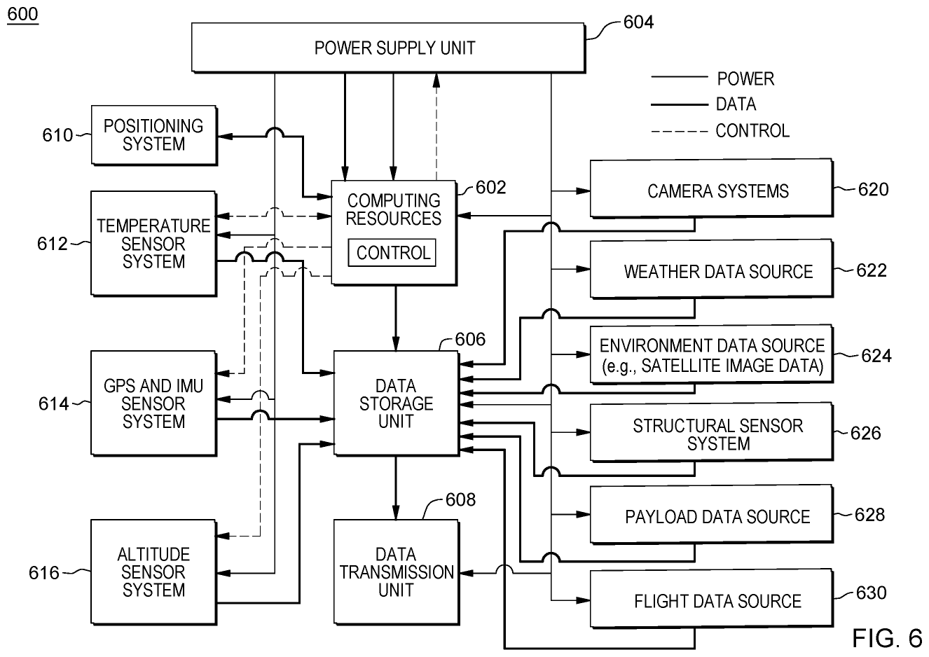

By way of explanation, FIG. 5A depicts another embodiment of a computing environment or system 500, which can incorporate, or implement, one or more control aspects of an embodiment of the present disclosure. In one or more implementations, system 500 is implemented as part of a computing environment, such as computing environment 100 described above in connection with FIG. 1. System 500 includes one or more computing resources 501 that execute program code 502 that implements, for instance, one or more aspects of a module or facility such as disclosed herein, and which includes an artificial-intelligence-based control 510, which can utilize one or more machine learning models 512, such as described herein. Data from one or more data sources 520, such as structural, geometric and dimensional data of the hot-air balloon, environmental data surrounding the balloon's projected flight path, payload data of the hot-air balloon flight, flight data on the hot-air balloon flight, satellite image data, global positioning system (GPS) data, altitude sensor data, temperature sensor data, and/or other data associated with generating one or more machine learning models 512, to be used in accordance with one or more aspects disclosed herein, is used by the artificial-intelligence-based control (e.g., cognitive engine or control) to train machine learning model(s) 512 to (for instance) produce a digital twin hot-air balloon model and to simulate the digital twin hot-air balloon model and one or more environmental conditions 514, and/or to generate auto-adjustment control signals for auto-adjusting the hot-air balloon flight path 530 based on one or more detected adverse environmental conditions to potentially effect the hot-air balloon on a projected flight path. In one implementation, system 500 can include, or utilize, one or more networks for interfacing various aspects of computing resource(s) 501, as well as one or more data sources 520 providing data, and one or more components, systems, etc., receiving an output, action, etc., 530 of machine learning model(s) 512 to facilitate performance of one or more artificial intelligence system operations. By way of example, the network(s) can be, for instance, a telecommunications network, a local-area network (LAN), a wide-area network (WAN), such as the Internet, or a combination thereof, and can include wired, wireless, fiber-optic connections, etc., operatively coupling the computing resource(s) 501 to the floating solar array and to other data sources. The network(s) can include one or more wired and/or wireless networks that are capable of receiving and transmitting data, including training data for the machine-learning model, and an output solution, recommendation, action, of the machine-learning model(s), such as discussed herein.

In one or more implementations, computing resource(s) 501 house and/or execute program code 502 configured to perform methods in accordance with one or more aspects of the present disclosure. By way of example, computing resource(s) 501 can be a computing-system-implemented resource(s). Further, for illustrative purposes only, computing resource(s) 501 in FIG. 5A is depicted as being a single computing resource. This is a non-limiting example of an implementation. In one or more other implementations, computing resource(s) 501 can, at least in part, be multiple separate computing resources or systems, such as one or more computing resources of a cloud-hosting environment, by way of example only.

Briefly described, in one embodiment, computing resource(s) 501 can include one or more processors, for instance, central processing units (CPUs). Also, the processor(s) can include functional components used in the integration of program code, such as functional components to fetch program code from locations in such as cache or main memory, decode program code, and execute program code, access memory for instruction execution, and write results of the executed instructions or code. The processor(s) can also include a register(s) to be used by one or more of the functional components. In one or more embodiments, the computing resource(s) can include memory, input/output, a network interface, and storage, which can include and/or access, one or more other computing resources and/or databases, as required to implement the machine-learning processing described herein. The components of the respective computing resource(s) can be coupled to each other via one or more buses and/or other connections. Bus connections can be one or more of any of several types of bus structures, including a memory bus or a memory controller, a peripheral bus, an accelerated graphics port, and a processor or local bus, using any of a variety of architectures. By way of example, but not limitation, such architectures can include the Industry Standard Architecture (ISA), the micro-channel architecture (MCA), the enhanced ISA (EISA), the Video Electronic Standard Association (VESA), local bus, and peripheral component interconnect (PCI). As noted, examples of a computing resource(s) or a computer system(s) which can implement one or more aspects disclosed are described further herein with reference to the figures.

In one embodiment, program code 502 executes an artificial-intelligence-based control 510 which includes (and optionally trains) one or more models 512. The models can be trained using training data that can include a variety of types of data, depending on the model and the data sources. In one or more embodiments, program code 502 executing on one or more computing resources 501 applies one or more algorithms of artificial-intelligence-based control 510 to generate and train the model(s), which the program code then utilizes to, for instance, produce a digital twin model of the hot-air balloon and to simulate the digital twin model of the hot-air balloon and one or more environmental conditions to potentially effect the hot-air balloon on a projected flight path, where the simulating can be in real time and concurrent with the hot-air balloon flight. Further, the machine learning model(s) further facilitates forecasting, based on the simulated digital twin model of the hot-air balloon and the one or more environmental conditions, presence of an adverse environmental condition to effect the hot-air balloon on the projected flight path, and to control, based on the forecasted adverse environmental condition on the projected flight path, the positioning system of the hot-air balloon to reposition the hot-air balloon onto a different flight path than the projected flight path to mitigate impact of the adverse environmental condition on the hot-air balloon. In an initialization or learning stage, program code 502 can train the one or more machine learning models 512 using obtained training data that can include, data from data sources 520, which in one or more embodiments, can include, for instance, structural, geometric and dimensional data of the hot-air balloon, environmental data surrounding the balloon's projected flight path, satellite image data, GPS data, payload data of the hot-air balloon flight, flight data of the hot-air balloon flight, weather data, including wind velocity and direction data, etc., such as described herein.

Data used to train the models, in one or more embodiments of the present disclosure, can include a variety of types of data, such as heterogeneous data generated by multiple data sources and/or data stored in one or more databases accessible by, the computing resource(s). Program code, in embodiments of the present disclosure, can perform data analysis to generate data structures, including algorithms utilized by the program code to predict and/or perform an action. As known, machine-learning-based modeling solves problems that cannot be solved by numerical means alone. In one example, program code extracts features/attributes from training data, which can be stored in memory or one or more databases. The extracted features can be utilized to develop a predictor function, h (x), also referred to as a hypothesis, which the program code utilizes as a model. In identifying machine learning model(s) 512, various techniques can be used to select features (elements, patterns, attributes, etc.), including but not limited to, diffusion mapping, principal component analysis, recursive feature elimination (a brute force approach to selecting features), and/or a random forest, to select the attributes related to the particular model. Program code can utilize one or more algorithms to train the model(s) (e.g., the algorithms utilized by program code), including providing weights for conclusions, so that the program code can train any predictor or performance functions included in the model. The conclusions can be evaluated by a quality metric. By selecting a diverse set of training data, the program code trains the model to identify and weight various attributes (e.g., features, patterns) that correlate to enhanced performance of the model.

In one or more embodiments, program code, executing on one or more processors, utilizes an existing cognitive analysis tool or agent (now known or later developed) to tune the model, based on data obtained from one or more data sources. In one or more embodiments, the program code can interface with application programming interfaces to perform a cognitive analysis of obtained data. Specifically, in one or more embodiments, certain application programing interfaces include a cognitive agent (e.g., learning agent) that includes one or more programs, including, but not limited to, natural language classifiers, a retrieve-and-rank service that can surface the most relevant information from a collection of documents, concepts/visual insights, tradeoff analytics, document conversion, and/or relationship extraction. In an embodiment, one or more programs analyze the data obtained by the program code across various sources utilizing one or more of a natural language classifier, retrieve-and-rank application programming interfaces, and tradeoff analytics application programing interfaces.

In one or more embodiments of the present disclosure, the program code can utilize one or more neural networks to analyze training data and/or collected data to generate an operational machine-learning model 512. Neural networks are a programming paradigm which enable a computer to learn from observational data. This learning is referred to as deep learning, which is a set of techniques for learning in neural networks. Neural networks, including modular neural networks, are capable of pattern (e.g., state) recognition with speed, accuracy, and efficiency, in situations where datasets are mutual and expansive, including across a distributed network, including but not limited to, cloud computing systems. Modern neural networks are non-linear statistical data modeling tools. They are usually used to model complex relationships between inputs and outputs, or to identify patterns (e.g., states) in data (i.e., neural networks are non-linear statistical data modeling or decision-making tools). In general, program code utilizing neural networks can model complex relationships between inputs and outputs and identify patterns in data. Because of the speed and efficiency of neural networks, especially when parsing multiple complex datasets, neural networks and deep learning provide solutions to many problems in multi-source processing, which program code, in embodiments of the present disclosure, can utilize in implementing a machine-learning model, such as described herein.

As noted, a digital twin is a virtual model designed to reflect a physical object or environmental condition. Applicable data sources provide data about different aspects of the object and/or environmental condition, with the data being used by the processing system and applied to the digital copy and/or environmental condition. Once informed of the data, the virtual model (i.e., the digital twin) can be used to run simulations, study performance issues and generate control actions. In one or more implementations, a digital twin is a virtual environment that can run a number of simulations in order to evaluate different aspects of the object and/or potential interaction with the environmental condition.

By way of example, FIG. 5B depicts a digital twin model of a hot-air balloon, which can be used in simulating one or more environmental conditions to potentially effect the hot-air balloon on a projected flight path, such as air quality at different altitudes of the projected flight path, and/or the existence of another structure that might result in a potential air-gap conflict between the hot-air balloon and the other structure. Based on a forecasted adverse environmental condition on the projected flight path, the data-analysis-based control is configured to control (e.g., activate) the positioning system of the hot-air balloon to reposition the hot-air balloon onto a different flight path than the projected flight path to mitigate impact of the adverse environmental condition on the hot-air balloon.

By way of further explanation, in one or more embodiments, satellite image data, and refraction of light analysis can be used along with weather parameters at different altitudes of the geographical area within which a hot-air balloon flight is occurring, or is to occur, for simulating the digital twin model of the hot-air balloon and the environmental condition(s) to identify, for instance, a safe trajectory in 3-D space for the hot-air balloon flight. In one embodiment, the data-analysis-based control steers the hot-air balloon to an appropriate safe flight path that includes, for instance, steering to a safe landing zone, flying to a different altitude, and/or recommending an altitude change-over point for the hot-air balloon by simulating, for instance, wind speed and direction, altitude, and location of one or more landing zones in real time, etc. In one or more implementations, using satellite image data analysis, air quality level at different altitudes is forecasted by simulating the digital twin model and the one or more conditions including, for instance, presence of carbon dioxide, smog, the different chemical particles, dust particles, aerosols at different altitudes, etc. (collectively referred to as aerosols). In one embodiment, a 3-D model of the aerosols is generated, with concentration of different particles at different altitudes and spread of the particles being identified and considered by the data-analysis-based control to, for instance, identify a safe flight path for the hot-air balloon to fly, so that any adverse environmental pollution can be avoided.

In one or more embodiments, the digital twin model of the hot-air balloon can be used to generate a lift profile of the balloon at different stages of the flight path and its corresponding air parameters (e.g., amount of air, temperature inside the balloon and outside, air density, differential temperature in different segments of the balloon, internal/external pressure), etc., so that the hot-air balloon is traveling at an optimal flight path, including in a pollution-free path. In one or more implementations, with a potential air-gap conflict or collision prediction by the data-analysis-based control with another balloon or physical structure, electrical cable, etc., the control auto-corrects the flight path of the hot-air balloon (using the positioning system associated with the hot-air balloon) to propel the hot-air balloon to a safe zone, and thereby mitigate the conflict. In one or more implementations, satellite and radar data can be used by the data-analysis-based control to identify relative position of, for instance, aerosol particles, as well as forecast the movement pattern of particles, which can be used by the data-analysis-based control to identify a safe trajectory for the hot-air balloon. In one embodiment, the control can be configured to automatically steer the hot-air balloon by activating and/or controlling the positioning system associated with the balloon to move the hot-air balloon to a different flight path than the projected flight path having the adverse environmental condition.

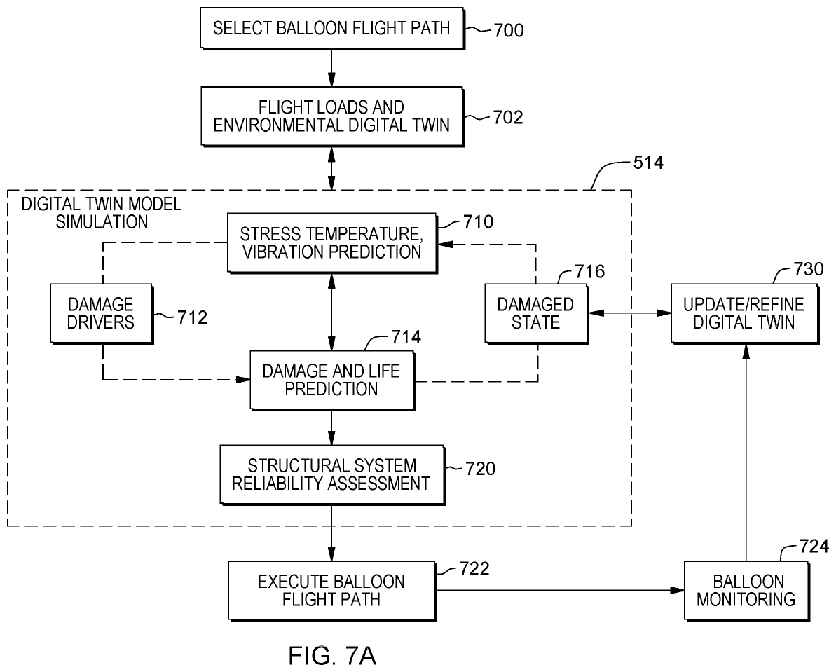

FIG. 6 depicts a further example of a computing environment to include and/or use one or more aspects of the present disclosure. In one or more embodiments, one or more aspects of computing environment 600 can be associated with the hot-air balloon being controlled and/or can reside remote from the hot-air balloon, such as at a cloud-based data center. As illustrated, computing environment 600 includes computing resources 602 which implement a control, such as the data-analysis-based control described herein. In one or more implementations, computing environment 600 is, or includes, a computing environment such as computing environment 100 described above in connection with FIG. 1, by way of example. In one embodiment, computing resources 602 and the data-analysis-based control are powered by a power supply unit 604. The data sources can include, for instance, a temperature sensor system 612, a global positioning system (GPS) and/or an inertial measurement unit (IMU) sensor system 614, an altitude sensor system 616, one or more camera systems 620, a weather data source 622 (obtained, for instance, from available online data sources), an environmental data source 624 (such as satellite image data to facilitate identifying one or more environmental conditions), as well as a structural sensor system 626, payload data source 628, and/or flight data source 630, as well as any other data source and/or other data relevant to data-analysis-based control of the hot-air balloon and dynamic control of the flight path of the hot-air balloon. Computing resources 602 access and use a data storage unit 606 to obtain and/or retain generated data from one or more of the data sources (or sensors) to, for instance, facilitate training the digital twin model and/or running simulations using the digital twin model, as well as a data transmission unit 608 to facilitate transmitting and receiving data, such as flight-related data 630 in the case where computing environment 600 is separate from the hot-air balloon. As noted, the hot-air balloon further includes a positioning system 610, which as noted, can be any of a variety of positioning systems that form a part of, or are connected to, the hot-air balloon, such as connected to the gondola. For instance, one or more adjustable and/or controllable positioning devices can be attached to the gondola of the hot-air balloon in order to facilitate repositioning the hot-air balloon. For instance, precision thrusters, such as propane-powered precision thrusters, and/or adjustable rotatable air-moving devices, such as one or more electric-powered rotatable air-moving devices, can be associated with the gondola to facilitate moving or repositioning the hot-air balloon from a projected flight path to a different flight path using one or more control and/or activation signals sent from the data-analysis-based control.

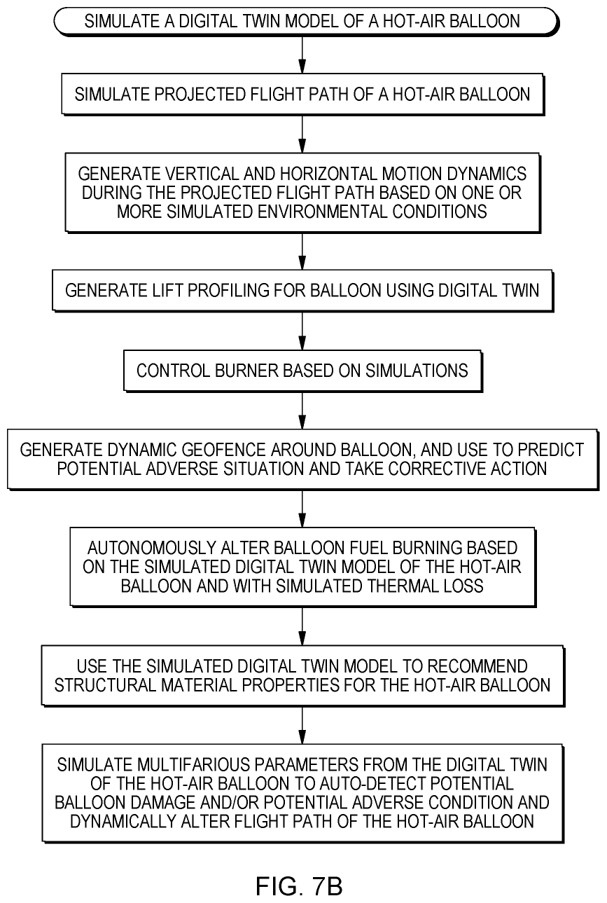

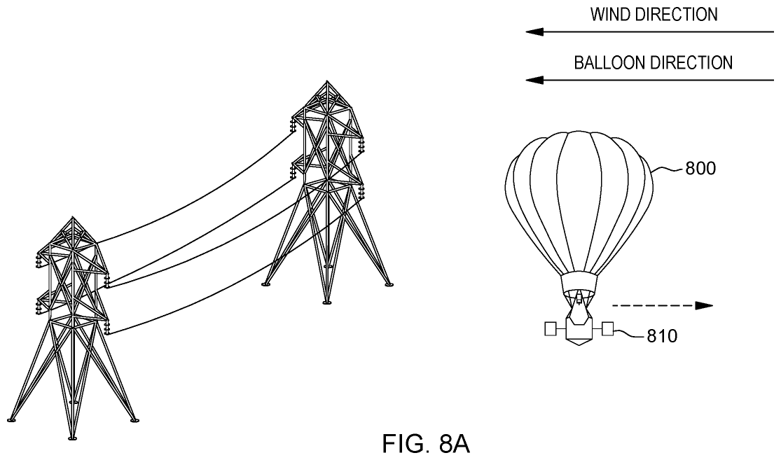

FIG. 7A depicts one example of a context-aware hot-air balloon flight control workflow, in accordance with one or more aspects of the present disclosure. As illustrated, the workflow includes selecting a hot-air balloon flight path 700 and obtaining hot-air balloon flight loads, relevant environmental data, weather data, etc. 702, for input to the digital twin model simulation 514, with the digital twin model simulation evaluating, for instance, the data to obtain stress, temperature, and/or vibration predictions 710 which can effect flight of the hot-air balloon, including, evaluating any potential damage drivers 712, such as an adverse environmental condition which could damage, or otherwise affect the hot-air balloon, to predict damage or life expectancy of the hot-air balloon 714, including, for instance, whether the hot-air balloon might experience a damaged state 716 due to, for instance, an encounter with an adverse environmental condition. Depending on digital twin model simulation processing, the digital twin model can be updated and/or refined 730. The digital twin model provides, in one embodiment, a reliability assessment of the structural system of the hot-air balloon 720 to verify continued flight of the hot-air balloon along the projected flight path 722. During hot-air balloon flight, the hot-air balloon structure and/or related environmental conditions can be monitored 724 and used to, for instance, further update and/or refine the digital twin model 730, in one embodiment.

FIG. 7B depicts another example of a context-aware hot-air balloon flight control workflow, in accordance with one or more aspects of the present disclosure. In this embodiment, a digital twin model of a hot-air balloon is simulated along with one or more environmental conditions 740. For instance, a digital twin model of the hot-air balloon is created as a virtual model using the structural, geometrical and dimensional properties of the hot-air balloon, and its corresponding Internet of Things (IoT) sensor data is obtained, along with real-time, environmental, payload and passenger data, from multifarious data sources, such as from multiple IoT sensors. The projected flight path of the hot-air balloon is simulated 742 using, for instance, weather data (wind speed, direction, time of day, etc.) and flight parameters (altitude at different times of ascending or descending). In one embodiment, the data-analysis-based control, using the digital twin, simulates an approximate flight path, and in one embodiment, a recommended safe landing location for the hot-air balloon.

In one or more implementations, vertical and horizontal motion dynamics are generated during the projected flight path based on one or more simulated environmental conditions 744. For instance, the data-analysis-based control can be configured to generate vertical and horizontal motion dynamics during the hot-air balloon flight, and thereby recommend/initiate altitude changeover points of the hot-air balloon by, in part, simulating wind speed and direction, altitude and a desired landing zone, in real time. The control process can, in one or more embodiments, generate a lift profile for the hot-air balloon using the digital twin model 746. For instance, the digital twin of the hot-air balloon can facilitate generating the lift profile inside the envelope or gondola during different stages of the flight path, and its corresponding air parameters (e.g., amount of air, temperature inside versus outside, air density, differential temperature in different segments of the gondola, internal and external pressure, etc.).

In one embodiment, the data-analysis-based control can control the hot-air balloon burner based on the simulations using the digital twin model 748. For example, the data-analysis-based control can be configured to determine the amount of fuel to be injected into the burner based on simulations of energy requirements, energy loss of the hot-air balloon, amount of lift and/or descent required, and other weather-based factors. For instance, in one implementation, the data-analysis-based control is configured to autonomously inject a desired amount of fuel into the burner for a specified period of time. In one embodiment, during occurrence of unwanted weather conditions, such as fog, rain, etc., the data-analysis-based control is able to detect and monitor the required temperature and air density to be maintained inside the envelope, and auto-adjust the fuel injection and burning to achieve the required vertical flight path. In one embodiment, during any point in the hot-air balloon flight, the control can dynamically simulate a nearest landing site and auto-adjust the flight path during descent.

In one or more embodiments, the control process further generates a dynamic geofence around the hot-air balloon, and uses the geofence, the digital twin and a predicted potential adverse condition or situation into taking corrective action 750. For instance, a dynamic geofence is generated by the data-analysis-based control around the hot-air balloon based on its direction and speed, and used to notify an operator of a potential situation where there is a geofence and/or air-gap conflict. For instance, the data-analysis-based control can be configured to auto-alert and/or take corrective action based on detection of a potential air-gap conflict between the hot-air balloon and another hot-air balloon, or between the hot-air balloon and any physical structure (such as a tree, building, electrical line, etc.). In one or more embodiments, the data-analysis-based control auto-corrects the projected flight path to a different flight path by propelling the hot-air balloon onto a different trajectory using the positioning system of the hot-air balloon to thereby mitigate an adverse environmental condition. Using machine learning and the digital twin model, the data-analysis-based control can also generate cooling approximations by simulating balloon heating and thermal losses, and thereby autonomously alter fuel burning and auto-venting to add hot air, or to let excess hot air out, to maintain a required altitude during different stages of the flight path, such as when ascending, or descending to a selected landing site, etc., 752.

In one embodiment, the simulating using the digital twin modeling also allows the control to recommend structural material properties for the hot-air balloon 754. For instance, different segments of the hot-air balloon can be evaluated by simulating the type of flight, operating payload, and/or operating environmental conditions, to recommend desired structural material properties 754 for a balloon flight. In one embodiment, the data-analysis-based control simulates multifarious parameters from the digital twin of the hot-air balloon to auto-detect potential balloon damage and/or potential adverse conditions, and dynamically alter flight path of the hot-air balloon 756. For instance, based on fabric elasticity and structural specification, the data-analysis-based control can auto-detect and send and alert as to potential structural fabric damage to the hot-air balloon by simulating multifarious parameters from the digital twin of the hot-air balloon. Further, in one embodiment, the digital twin model can be used by the data-analysis-based control to monitor a potential adverse condition, such as a fire, and to auto-initiate a fire-fighting system on the hot-air balloon based on the fire incident location, and dynamically alter the flight path of the hot-air balloon to, for instance, a nearest landing zone.

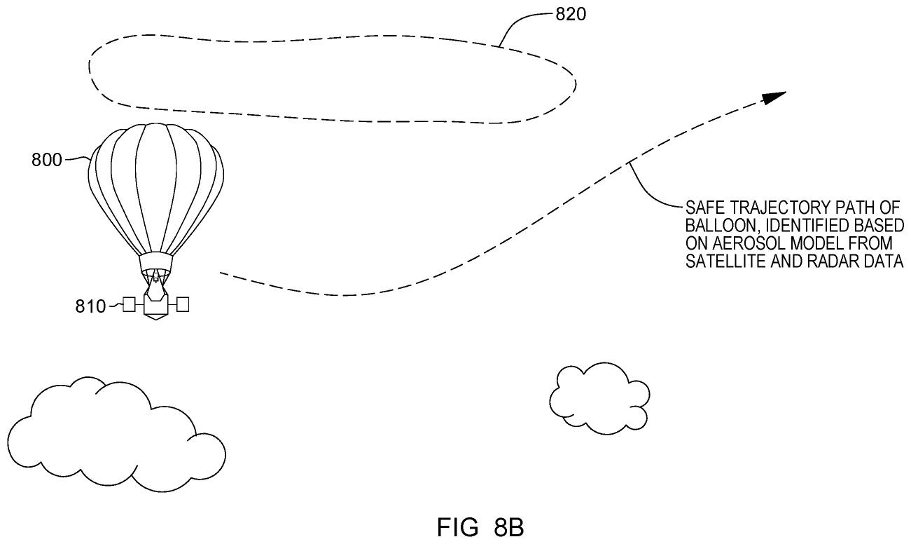

FIGS. 8A & 8B depict two examples of adverse environmental conditions that the data-analysis-based control described herein can address through simulating the digital twin model of the hot-air balloon and one or more environmental conditions to potentially effect the hot-air balloon on a projected flight path. In FIG. 8A, hot-air balloon 800 is drifting towards a transmission tower, based on the direction of wind. The transmission tower is an example of an adverse environmental condition. The data-analysis-based control, by simulating the digital twin model of the hot-air balloon and one or more environmental conditions, determines that a different flight path is needed, and controls positioning system 810 of the hot-air balloon to reposition or move the hot-air balloon onto a different flight path, which in this case, is away from the transmission tower. In FIG. 8B, the adverse environmental condition potentially effecting hot-air balloon 800 is a region of high concentration of aerosols 820 that could potentially negatively affect integrity of the hot-air balloon itself, or the occupants of the hot-air balloon. In this case, the data-analysis-based control, by simulating the digital twin model of the hot-air balloon and the one or more environmental conditions, determines a safe path for the balloon and controls the positioning system 810 of the hot-air balloon to reposition the hot-air balloon onto the different flight path in order to mitigate impact of the adverse environmental condition on the hot-air balloon.

By way of further explanation, additional details or aspects of a data-analysis-based control for hot-air balloon flight such as disclosed herein are provided below. In one or more implementations, the control obtains structural, geometric, and/or dimensional data on the hot-air balloon in order to generate the digital twin model of the hot-air balloon. The obtained data can include data on the type of envelope fabric, heat resistance of the envelope fabric, type and material properties of ropes used in the hot-air balloon, type of burner and capacity of the burner, type of fuel used in the burner, passenger cabin material, safety equipment, data on the fabric used at the skirt of the hot-air balloon, where the burner is located, etc. As noted, the skirt needs to endure substantially higher temperatures than the rest of the envelope. In one embodiment, heat-resistant synthetic fabric can be used in that area. Additionally, the structural, geometric and/or dimensional data of the hot-air balloon, and its corresponding Internet of Things (IoT) sensor data, along with real-time environmental data, as well as payload and passenger data from multifarious sensors, such as multifarious IoT sensors, can be used. The data can include data on empty payload weight of the hot-air balloon, fully-loaded payload weight of the hot-air balloon, envelope/gondola diameter data, envelope/gondola volume data, burner capacity data, fuel tank capacity data, etc.

In one or more embodiments, the data-analysis-based control ingests environmental data for the hot-air balloon flight including, for instance, wind data, temperature data for different vertical altitudes, energy loss data, drag coefficient data during different flight ascents and descents, specific heat data, gravitational constant data, lift data, air mass flow rate through the inlet and outlet data, internal and external pressure data, internal and external temperature data, and/or energy flow/loss/gain at different altitudes of the hot-air balloon flight.

In one or more embodiments, the data-analysis-based control ingests further environmental data for the hot-air balloon flight, including wind data and temperature and speed data at different vertical profiles of the flight, energy loss data, wind direction data, whether other hot-air balloons are in the geographical area of the hot-air balloon flight, take-off and landing site safety profile data, time of day data, duration of flight data, etc.

In one or more embodiments, the data-analysis-based control ingests passenger-related data for the hot-air balloon flight including, for instance, passenger payload data, and passenger safety data requirements.

In one or more implementations, the data-analysis-based control analyzes flight property data of the hot-air balloon including, for instance, time of day data, duration of flight data, and/or possible landing site data, etc.

In one or more embodiments, the data-analysis-based control creates, or otherwise obtains, a digital twin of the hot-air balloon, and simulates the digital twin and one or more environmental conditions. For instance, weather-related data and flight parameter data (e.g., altitude during different times of ascending, descending, etc.) can be used in combination with the digital twin to simulate an approximate flight path and, for instance, a nearest safe location for landing the hot-air balloon. In addition, in one embodiment, using weather data forecasts, the data-analysis-based control can use the digital twin model to alter the flight path through simulation, including duration or time of the flight, using artificial intelligence (AI) and machine learning techniques.

In one or more embodiments, the data-analysis-based control generates vertical thresholds during various segments of the hot-air balloon flight path, as well as generates horizontal thresholds during various segments of the hot-air balloon flight path. In addition, the data-analysis-based control is configured to generate vertical and horizontal motion dynamics during the hot-air balloon flight.

In one or more embodiments, the data-analysis-based control is configured to recommend an altitude change at different points in the flight path, where during a changeover point, the hot-air balloon can descend lower or ascend higher, based on real-time simulations of the environmental conditions, such as wind speed and direction, altitude and landing zone. In one embodiment, the digital twin model of the hot-air balloon generates control lift profiling inside the balloon envelope during different stages of the flight path, as well as the corresponding air parameters of the flight.

In one embodiment, the data-analysis-based control estimates the amount of fuel to be injected into the burner based on simulations of energy requirement, energy loss of the hot-air balloon, the amount of lift/descent required, and other environmental conditions. In one embodiment, the data-analysis-based control is configured to autonomously inject the amount of fuel required into the burner for a specified period of time, based on the simulation of the digital twin model and the one or more environmental conditions. As an example, the data-analysis-based control, through a simulation of the digital twin model and the one or more environmental conditions is able to detect potential occurrence of unwanted weather conditions, such as fire, rain, etc., and to alter the projected flight path of the hot-air balloon to, for instance, mitigate impact of the adverse environmental condition on the hot-air balloon. In one embodiment, the data-analysis-based control detects a required temperature and air density that needs to be maintained inside the envelope, and thereby auto-adjusts the fuel injection and burning to achieve the required vertical flight path.

In one or more embodiments, the data-analysis-based control generates a dynamic geofence around the hot-air balloon based on flight direction and speed. Using the dynamic geofence, the data-analysis-based control can identify a potential air-gap conflict between the hot-air balloon and another structure, where the adverse environmental condition includes the potential air-gap conflict. In one or more embodiments, the data-analysis-based control sends an alert of the potential adverse situation using, for instance, available wireless communication technology. For instance, in one embodiment, the data-analysis-based control automatically sends an alert of the potential air-gap conflict, and can take corrective action by controlling the positioning system of the hot-air balloon in order to relocate the hot-air balloon to prevent contact of the hot-air balloon with another hot-air balloon or another physical structure.

In one or more implementations, multiple hot-air balloons can be wirelessly coupled in communication, and the data-analysis-based control can, in such a situation, autonomously relate vertical and/or horizontal path adjustments to other hot-air balloons (or other hot-air balloon operators) in the geographical area to assist with avoiding an air-gap conflict between two or more hot-air balloons.

In one or more embodiments, during any point in a hot-air balloon flight, the data-analysis-based control can dynamically simulate a nearest landing site, and auto-adjust the flight path during hot-air balloon descent to that landing path, if desired.

In one embodiment, using machine learning and artificial intelligence (AI) techniques, the data-analysis-based control uses the digital twin model to generate cooling approximations by simulating heating and thermal losses, and thereby autonomously alter fuel burning within the hot-air balloon, and auto-venting of excess heat, in order to maintain a desired air temperature within the hot-air balloon during different stages of hot-air balloon flight, such as during ascent, or during descent.

In one or more embodiments, the data-analysis-based control uses the digital twin model in recommending structural material properties for different segments of the hot-air balloon through simulating, for instance, different hot-air balloon flights, with different operating payloads and/or different environmental operating conditions.

In one or more embodiments, based on envelope fabric elasticity and structural analysis, the data-analysis-based control can auto-detect and send an alert on potential structural damage to the envelope of the hot-air balloon by simulating multifarious parameters from the digital twin of the hot-air balloon.

By way of further example, if there is a helium-filled balloon and there is no wind, the balloon will float in the sky and the line attached to the balloon will be completely vertical. There are three forces acting on the balloon in that case. There is the downward-pulling gravitational force that depends on both the mass of the object (m) and the gravitational field (g=9.8 N/kg). Since the balloon displaces air, it has a buoyancy force that is equal to the weight of the air displaced (Archimedes' principle). If the balloon only had these two forces, then the net force would most likely be upward and the balloon would accelerate away.

The other force is a downward tension force (T) with a magnitude to make the net force equal to zero. With a zero net force, the balloon is in equilibrium and stays at rest, as represented by the following formula:

$${F}_{net - y} = {F}_{B} - mg - T = 0$$

Gravitational force (m*g), and the tension is the value it needs to be in order to make the total force zero (it's a force of constraint). Since the buoyancy force is the weight of the air displaced, the volume of the balloon (V) and the density of air (p) are to be determined. Assuming that the balloon is a sphere with a radius R, then the buoyancy force would be:

$${F}_{B} = ρ g ( \frac{4}{3} π {R}^{3} )$$

Suppose the wind is blowing horizontally with some velocity (v). This means there will be another force on the balloon, that is, an air drag force. This air drag can be modeled as a force in the same direction as the wind with a magnitude that depends on the wind speed, the cross-sectional area of the balloon (A), the shape of the balloon (C), and the density of air (ρ), where the cross section of the balloon is a circle with a radius R, which makes the area equal to πR² (the area of a circle). The result is the following equation:

F_{D}=½ρACv²

Since there is a horizontal force from the wind, there has to be another horizontal force so that the net force in that direction is zero. This extra horizontal force comes from the string as it pulls at an angle. If the balloon is still in equilibrium, the net force must be zero in the both the horizontal (x) and vertical (y) directions. The tension in the string has a component of force in both the x and y directions such that the following two equations would be true:

$${F}_{net - x} = {F}_{D} - T cos θ = 0 \\ {F}_{net - y} = {F}_{B} - mg - T sin θ = 0$$

Since the tension is a constraint force, there is not a direct way to calculate that force. The T in the y-force equation can be used to substitute it into the x-force equation, which results in an expression for the lean angle of the balloon. Remember that the drag force depends on both the radius of the balloon and the velocity of the wind, but the buoyancy force also depends the radius (because of the volume). The result is the following equation:

$$tan θ = \frac{\frac{4}{3} π {R}^{3} pg - mg}{\frac{1}{2} ρπ {R}^{2} {Cv}^{2}}$$

The same or similar analysis to that described above can be used by the data-analysis-based control described herein to facilitate, for instance, autonomous control of the hot-air balloon, and in particular, the positioning system of the hot-air balloon to selectively reposition the hot-air balloon onto a different flight path than a projected flight path to, for instance, mitigate impact of an adverse environmental condition on the hot-air balloon, such as described.

The terminology used herein is for the purpose of describing particular embodiments only and is not intended to be limiting of the disclosure. As used herein, the singular forms “a”, “and” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A computer-implemented method comprising:
obtaining a data-analysis-based control to control a flight path of a hot-air balloon, the hot-air balloon including a positioning system to facilitate repositioning the hot-air balloon, and the data-analysis-based control comprising:
simulating a digital twin model of the hot-air balloon and one or more environmental conditions to potentially effect the hot-air balloon on a projected flight path;
forecasting, based on the simulated digital twin model of the hot-air balloon and the one or more environmental conditions, presence of an adverse environmental condition to effect the hot-air balloon on the projected flight path; and
controlling, based on the forecasted adverse environmental condition on the projected flight path, the positioning system of the hot-air balloon to reposition the hot-air balloon onto a different flight path than the projected flight path to mitigate impact of the adverse environmental condition on the hot-air balloon.

2. The computer-implemented method of claim 1, wherein simulating the digital twin model with the one or more environmental conditions includes using, by the data-analysis-based control, satellite image data analysis to predict air quality at different altitudes of the projected flight path, the one or more environmental conditions to potentially effect the hot-air balloon including the predicted air quality at different altitudes of the projected flight path.

3. The computer-implemented method of claim 2, wherein predicting the air quality at different altitudes of the projected flight path includes using, by the data-analysis-based control, refraction of light data analysis to determine from the satellite image data presence of one or more adverse air qualities within the projected flight path of the hot-air balloon.

4. The computer-implemented method of claim 2, wherein the data-analysis-based control further comprises modeling in 3-D space, along with the digital twin model, an environmental condition of the one or more environmental conditions, and wherein the data-analysis-based control controls the positioning system of the hot-air balloon to reposition the hot-air balloon onto the different flight path to avoid the adverse environmental condition using, at least in part, the modeling in 3-D space of the environmental condition.

5. The computer-implemented method of claim 4, wherein the environmental condition comprises aerosols at one or more different altitudes, and the modeling includes modeling concentration of one or more different particles at the one or more different altitudes, and spread of the one or more different particles in 3-D space, to facilitate identifying the different flight path for the hot-air balloon, where the different flight path has a lower concentration of the one or more different particles than the projected flight path.

6. The computer-implemented method of claim 1, wherein the data-analysis-based control further comprises:
generating, as part of the simulated digital twin model, a lift characterization of the hot-air balloon, and one or more corresponding air parameters; and
wherein the control includes using, at least in part, the lift characterization of the hot-air balloon and the one or more corresponding air parameters, in controlling the positioning system to reposition the hot-air balloon to the different flight path to mitigate impact of the adverse environmental condition on the hot-air balloon.

7. The computer-implemented method of claim 1, wherein the data-analysis-based control further comprises obtaining multifarious data for the hot-air balloon and the one or more environmental conditions, and using the multifarious data in simulating the digital twin model and the one or more environmental conditions in real time to simulate conditions of flight dynamics of the hot-air balloon with context awareness.

8. The computer-implemented method of claim 7, wherein the multifarious data comprises data selected from the group consisting of: data properties of the hot-air balloon, data properties of the flight of the hot-air balloon, weather data for the flight of the hot-air balloon, and particle concentration at different altitudes of the projected flight path.

9. The computer-implemented method of claim 1, wherein the data-analysis-based control further comprises:
generating a dynamic geofence around the hot-air balloon based on flight direction and speed;
using the dynamic geofence around the hot-air balloon to identify a potential air-gap conflict between the hot-air balloon and another structure, where the adverse environmental condition comprises the potential air-gap conflict; and
wherein controlling the positioning system comprises taking corrective action to avoid the potential air-gap conflict between the hot-air balloon and the another structure.

10. The computer-implemented method of claim 1, wherein the simulating further comprises simulating a landing site for the hot-air balloon, and the data-analysis-based control further comprises auto-adjusting a landing flight path of the hot-air balloon using the positioning system during descent of the hot-air balloon based on simulating the landing site.

11. A computer system comprising:
a memory; and
at least one processor in communication with the memory, wherein the computer system is configured to perform a method, the method comprising:
obtaining a data-analysis-based control to control a flight path of a hot-air balloon, the hot-air balloon including a positioning system to facilitate repositioning the hot-air balloon, and the data-analysis-based control comprising:
simulating a digital twin model of the hot-air balloon and one or more environmental conditions to potentially effect the hot-air balloon on a projected flight path;
forecasting, based on the simulated digital twin model of the hot-air balloon and the one or more environmental conditions, presence of an adverse environmental condition to effect the hot-air balloon on the projected flight path; and
controlling, based on the forecasted adverse environmental condition on the projected flight path, the positioning system of the hot-air balloon to reposition the hot-air balloon onto a different flight path than the projected flight path to mitigate impact of the adverse environmental condition on the hot-air balloon.

12. The computer system of claim 11, wherein simulating the digital twin model with the one or more environmental conditions includes using, by the data-analysis-based control, satellite image data analysis to predict air quality at different altitudes of the projected flight path, the one or more environmental conditions to potentially effect the hot-air balloon including the predicted air quality at different altitudes of the projected flight path.

13. The computer system of claim 12, wherein the data-analysis-based control further comprises modeling in 3-D space, along with the digital twin model, an environmental condition of the one or more environmental conditions, and wherein the data-analysis-based control controls the positioning system of the hot-air balloon to reposition the hot-air balloon onto the different flight path to avoid the adverse environmental condition using, at least in part, the modeling in 3-D space of the environmental condition.

14. The computer system of claim 13, wherein the environmental condition comprises aerosols at one or more different altitudes, and the modeling includes modeling concentration of one or more different particles at the one or more different altitudes, and spread of the one or more different particles in 3-D space, to facilitate identifying the different flight path for the hot-air balloon, where the different flight path has a lower concentration of the one or more different particles than the projected flight path.

15. The computer system of claim 11, wherein the data-analysis-based control further comprises obtaining multifarious data for the hot-air balloon and the one or more environmental conditions, and using the multifarious data in simulating the digital twin model and the one or more environmental conditions in real time to simulate conditions of flight dynamics of the hot-air balloon with context awareness.

16. The computer system of claim 11, wherein the data-analysis-based control further comprises:
generating a dynamic geofence around the hot-air balloon based on flight direction and speed;
using the dynamic geofence around the hot-air balloon to identify a potential air-gap conflict between the hot-air balloon and another structure, where the adverse environmental condition comprises the potential air-gap conflict; and
wherein controlling the positioning system comprises taking corrective action to avoid the potential air-gap conflict between the hot-air balloon and the another structure.

17. A computer program product comprising:
one or more computer readable storage media and program instructions collectively stored on the one or more computer readable storage media readable by at least one processing circuit to:
obtain a data-analysis-based control to control a flight path of a hot-air balloon, the hot-air balloon including a positioning system to facilitate repositioning the hot-air balloon, and the data-analysis-based control comprising:
simulating a digital twin model of the hot-air balloon and one or more environmental conditions to potentially effect the hot-air balloon on a projected flight path;
forecasting, based on the simulated digital twin model of the hot-air balloon and the one or more environmental conditions, presence of an adverse environmental condition to effect the hot-air balloon on the projected flight path; and
controlling, based on the forecasted adverse environmental condition on the projected flight path, the positioning system of the hot-air balloon to reposition the hot-air balloon onto a different flight path than the projected flight path to mitigate impact of the adverse environmental condition on the hot-air balloon.

18. The computer program product of claim 17, wherein the program instructions readable by the at least one processing circuit to simulate the digital twin model with the one or more environmental conditions are further readable by the at least one processing circuit to use, by the data-analysis-based control, satellite image data analysis to predict air quality at different altitudes of the projected flight path, the one or more environmental conditions to potentially effect the hot-air balloon including the predicted air quality at different altitudes of the projected flight path.

19. The computer program product of claim 18, wherein the program instructions are further readable by the at least one processing circuit to model in 3-D space, along with the digital twin model, an environmental condition of the one or more environmental conditions, and wherein the data-analysis-based control controls the positioning system of the hot-air balloon to reposition the hot-air balloon onto the different flight path to avoid the adverse environmental condition using, at least in part, the modeling in 3-D space of the environmental condition.

20. The computer program product of claim 17, wherein the program instructions are further readable by the at least one processing circuit to obtain multifarious data for the hot-air balloon and the one or more environmental conditions, and use the multifarious data in simulating the digital twin model and the one or more environmental conditions in real time to simulate conditions of flight dynamics of the hot-air balloon with context awareness.
